(19) United States
(12) Patent Application Publication
(10) Pub. No.: US 2005/0253142 A1
(43) Pub. Date: Nov. 17, 2005

(54) Solar cell and its manufacturing method

(75) Inventors: Takayuki Negami, Hirakata-shi (JP); Shinichi Shimakawa, Ikoma-shi (JP); Takuya Satoh, Yamatokooriyama-shi (JP); Shigeo Hayashi, Souraku-gun (JP)

Correspondence Address: HAMRE, SCHUMANN, MUELLER & LARSON P.C., P.O. BOX 2902, MINNEAPOLIS, MN, 55402, US

(73) Assignee: MATSUSHITA ELECTRIC INDUSTRIAL CO., LTD, OSAKA 571-8501 (JP)

(21) Appl. No.: 10/517,945

(22) PCT Filed: Sep. 10, 2003
(86) PCT No.: PCT/JP03/11533

§ 371 Date: Dec. 13, 2004

(30) Foreign Application Priority Data
Sep. 11, 2002 (JP) 2002-266087

(51) Int. Cl. H01L 31/0256; H01L 21/36

(52) U.S. Cl. 257/65; 438/95; 438/479; 257/613

(57) ABSTRACT

A solar cell includes a conductive substrate, and an insulating layer, a conducting layer and a semiconductor layer that are disposed on the substrate. A through hole is formed so as to penetrate the insulating layer and the conducting layer, and the through hole is filled with a semiconductor that composes the semiconductor layer. At least one element selected from the elements composing the conductive substrate diffuses into the semiconductor with which the through hole is filled.

### TECHNICAL FIELD

The present invention relates to a solar cell and a method for manufacturing the same.

### BACKGROUND ART

A thin-film solar cell using CuInSe₂ (CIS) or Cu(In, Ga)Se₂ (CIGS) that is a solid solution of CIS with Ga, as a optical-absorption layer (hereinafter, it may be called as a CIS solar cell or a CIGS solar cell, respectively), is known. CIS and CIGS are compound semiconductor layers (chalcopyrite structured semiconductor layers) comprising elements from each of groups Ib, IIIB and VIb. It is reported that such a CIS solar cell and a CIGS solar cell have an advantage of showing a high energy conversion efficiency and being free from a deterioration of efficiency caused by irradiation with light.

Since a CIS solar cell and a CIGS solar cell can be formed by laminating thin films, they can be formed on a flexible substrate, and an integrated solar cell can be manufactured by forming a plurality of serially connected unit cells on a substrate. In order to form a high-quality CIS or CIGS film, a formation temperature of 500° C. or more is currently necessary. Therefore, it is advantageous to use a metal foil with high heat durability as a substrate to manufacture a flexible CIS or CIGS solar cell with high efficiency. However, when using a metal foil alone for a substrate, an integrated solar cell cannot be manufactured, because the metal foil has electrical conductivity. Thus a solar cell using a metal foil with an insulating layer formed on a surface thereof as a substrate has been proposed.

For example, Sato, et al. presented a report regarding a CIGS solar cell, titled “CIGS Solar Cells on Stainless Steel Substrates Covered with Insulating Layers” at 12th International Photovoltaic Science and Engineering Conference held in 2001 (refer to Technical Digest of 12th International Photovoltaic Science and Engineering Conference, Korea, 2001, P. 93). According to the report, Sato, et al. formed a SiO₂ layer as an insulating layer on a stainless foil, which was used as a substrate so as to obtain a CIGS solar cell having a conversion efficiency of 12.2%. Also, M. Powalla et al. presented a report regarding a CIGS solar cell, titled “First Results of the CIGS Solar Module Pilot Production” at 17th European Photovoltaic Solar Energy Conference held in 2001 (refer to Proceeding of 17th European Photovoltaic Solar Energy Conference, Germany, 2001, P. 983). According to the report, Powalla et al. manufactured an integrated CIGS solar cell by using as a substrate a Cr foil with an insulating layer having a two-layer structure consisting an Al₂O₃ layer and a SiO₂ layer formed thereon. However, since the insulation properties of the insulating layer were not sufficient, the conversion efficiency was as low as 6.0%. As is understood from the above-mentioned results, the sufficient insulation properties by an insulating layer are necessary to obtain a high conversion efficiency from an integrated solar cell that includes a flexible metal substrate.

Meanwhile, in a solar cell array in which solar cell modules are serially connected to obtain a high electric power, a bypass diode showing a rectification in a reverse direction to that of a p-n junction in a solar cell needs to be connected in parallel to the solar cell module for the following reason. When one of modules fails in the generation of electric power because of, for example, being damaged or being shaded, electricity produced by normally operating modules can bypass the inoperative module. By providing such a bypass diode, electricity can be supplied normally even when there is an inoperative module. Although such a bypass diode is not generally provided in each solar cell in a module, a configuration of a Si solar cell including a bypass diode formed in a cell has been reported. There has been no example of such a report regarding a thin-film solar cell.

In a solar cell module, when one of the unit cells is damaged, partly stained on its surface or partly shaded, the unit cell does not produce electric power, and accordingly the efficiency of the solar cell module is degraded. Moreover, if the solar cell module in such a condition is exposed to sunshine for a long time, normally operating cells also may be damaged. Therefore, it is preferable to form a bypass diode in a solar cell module. However, when forming a bypass diode in a thin-film solar cell by a general conventional method, there may occur such problems that the manufacturing process increases in number and becomes complicated, and that the property of a p-n junction diode in a solar cell deteriorates during the formation of a bypass diode.

Whereas, it is possible for a thin-film solar cell to be enlarged in area, and to reduce the manufacturing cost. However, since a metal substrate has rougher asperities on its surface than those of a glass or an organic film, even if a thick insulating layer is formed on the surface of a metal substrate in a large area, the surface partly may not be covered with the insulating layer. A conductive film (generally a metal film) that serves as a backside electrode of a solar cell connects to the part of the metal substrate uncovered by the insulating layer directly, which generates a short circuit there. Consequently, in order to form a thin-film solar cell with a high converting efficiency using a metal substrate, it is necessary to remove a short circuit portion between the metal substrate and the backside electrode (the conductive film) after the formation of the insulating layer.

### DISCLOSURE OF THE INVENTION

In light of the above, it is an object of the present invention to provide a solar cell with a novel structure having an excellent property and reliability, and a method for manufacturing the same.

In order to attain the above-mentioned object, a first solar cell of the present invention includes: a conductive substrate; and an insulating layer, a conducting layer and semiconductor layer that are disposed on the substrate in this order. A through hole is formed so as to penetrate the insulating layer and the conducting layer, and the through hole is filled with a semiconductor that composes the semiconductor layer.

Moreover, a second solar cell of the present invention includes: a conductive substrate; an insulating layer formed on the substrate; and a plurality of unit cells that are formed on the insulating layer and are connected in series. Each unit cell includes a conducting layer and a semiconductor layer that are disposed on the insulating layer in this order, in which a through hole is formed so as to penetrate the insulating layer and the conducting layer, and the through hole is filled with a semiconductor that composes the semiconductor layer.

In the solar cell of the present invention, at least one element selected from the elements composing the substrate may diffuse into the semiconductor with which the through hole is filled.

In the solar cell of the present invention, the substrate may be made of a metal alloy comprising at least two elements selected from Ti, Cr, Fe and Ni, or stainless steel.

In the solar cell of the present invention, the insulating layer may be made of at least one selected from the group consisting of SiO₂, TiO₂, Al₂O₃, Si₃N₄, TiN and glass.

In the solar cell of the present invention, the conducting layer may include Mo.

In the solar cell of the present invention, the semiconductor layer may be made of a compound semiconductor comprising an element from group Ib, an element from group IIIb, and an element from group VIb.

In the solar cell of the present invention, the element from group Ib may be Cu, the element from group IIIB may be at least one element selected from In and Ga, and the element from group VIb may be at least one element selected from Se and S.

In the solar cell of the present invention, the compound semiconductor may be a p-type semiconductor, and the semiconductor with which the through hole may be filled a p-type or n-type semiconductor having higher resistance than the p-type semiconductor of the compound semiconductor.

Furthermore, a manufacturing method of the present invention is a method for manufacturing a solar cell that includes a conductive substrate, and an insulating layer, a conducting layer and semiconductor layer that are disposed on the substrate in this order, and includes the steps of:
(i) laminating the insulating layer and the conducting layer on the substrate in this order;
(ii) forming a through hole so as to penetrate the insulating layer and the conducting layer; and

(iii) forming the semiconductor layer in the through hole and over the conducting layer.

In the above-mentioned manufacturing method of the present invention, the through hole may be formed by letting electric current flow between the conducting layer and the substrate in the step (ii).

The above-mentioned manufacturing method of the present invention may further include a step of removing a part of the conducting layer to be in a strip shape, so that the conducting layer is split off into plural strips, which is conducted after the step (i) and before the step (ii). Additionally, in the step (ii), the through hole may be formed by letting electric current flow between two conducting layers selected from the plural strips of the conducting layers.

### BRIEF DESCRIPTION OF DRAWINGS

FIG. 1 is a cross-sectional view of an example of a solar cell of the present invention.

FIG. 2A is a cross-sectional view showing a process in an example of a manufacturing method of the present invention.

FIG. 2B is a cross-sectional view of a through hole formed in the process shown in FIG. 2A.

FIG. 3A is a cross-sectional view of a part of a solar cell of the present invention.

FIG. 3B is a schematic view of the function of the part shown in FIG. 3A.

FIG. 4 is a cross-sectional view of another example of a solar cell of the present invention.

FIG. 5A is a cross-sectional view of a process in another example of a manufacturing method of the present invention.

FIG. 5B is a cross-sectional view of through holes formed in the process shown in FIG. 5A.

FIG. 6 is a cross-sectional view of still another example of a solar cell of the present invention.

FIG. 7 is a diagram showing a relationship between a value of resistance between a conductive substrate and a conducting layer and an applied voltage in a manufacturing method of the present invention.

FIG. 8 is a diagram showing a change in resistance between two conducting layers on both sides of a groove, which shows the state prior to and after the application of the voltage across the two conducting layers.

### BEST MODE FOR CARRYING OUT THE INVENTION

The following is a description of embodiments of the present invention, with reference to the accompanying drawings. It should be noted that the present invention is not limited to the embodiments described herein.

### Embodiment 1

In Embodiment 1, an example of a configuration of a thin-film solar cell of the present invention will be described.

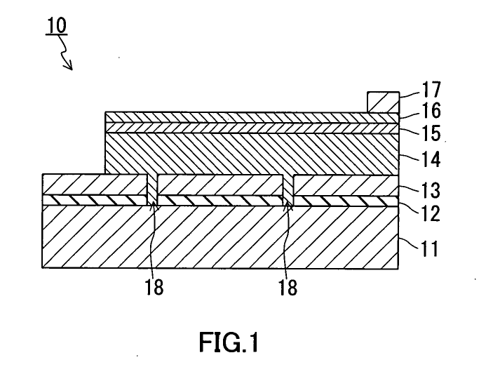

The cross-sectional view of a solar cell of Embodiment 1 is shown in FIG. 1. As shown in FIG. 1, a solar cell 10 of Embodiment 1 includes a conductive substrate 11, an insulating layer 12 formed on the conductive substrate 11, a conducting layer 13 formed on the insulating layer 12, a semiconductor layer 14 formed on the conducting layer 13, a window layer 15 formed on the semiconductor layer 14, a transparent conductive film 16 formed on the window layer 15, and an extraction electrode 17 formed on the transparent conductive film 16. Moreover, a second window layer made of a semiconductor or an insulator may be further provided between the window layer 15 and the transparent conductive film 16.

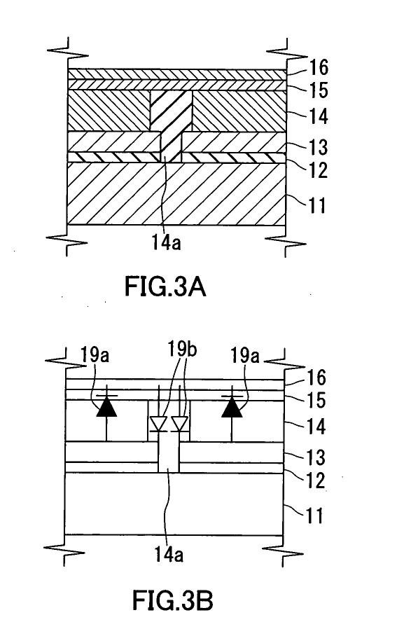

In the insulating layer 12 and the conducting layer 13, a through hole 18 is formed so as to penetrate them. The through hole 18 is filled with a semiconductor that composes the semiconductor layer 14. In the semiconductor layer 14 formed in the through hole 18 and the semiconductor layer 14 located over the through hole 18, at least one element selected from the elements that compose the conductive substrate 11 diffuses and forms a semiconductor layer 14a, which has different characteristics from those of the other part (refer to an enlarged view in FIG. 3A). For example, if the semiconductor layer 14 is a p-type semiconductor, the semiconductor layer 14a is a p-type or n-type semiconductor having higher resistance than that of the semiconductor layer 14. A carrier density of the semiconductor layer 14a may be, for example, 10¹⁵ cm⁻³ or lower. The semiconductor layer 14a, in which the element composing the conductive substrate 11 diffuses, reaches the window layer 15.

The conductive substrate 11 may be made of a metal, for example, a metal alloy that contains at least two elements selected from Ti, Cr, Fe and Ni, or a stainless steel. For the metal alloy, for example, a Fe—Ni alloy may be used. Among these materials, a stainless steel is preferable, because a substrate of made of the stainless steel can keep its strength even when it is made thin.

The insulating layer 12 is composed of an insulative material, more specifically, at least one material selected from the group consisting of SiO₂, TiO₂, Al₂O₃, Si₃N₄, TiN and a glass. A multilayer film laminating plural layers of these materials also can be used for the insulating layer 12.

The conducting layer 13 can be formed of a conductive material (for example, a metal), and can contain molybdenum (Mo). More specifically, a layer of Mo, a layer of a molybdenum compound (for example, MoSe₂), or a multilayer film laminating these two layers can be used for the conducting layer 13.

For the semiconductor layer 14 that can function as an optical absorption layer, for example, a chalcopyrite structured semiconductor that contains an element from group Ib, an element from group IIIB and an element from group VIb can be used. The element from group Ib can be Cu, and the element from group IIIB can be at least one element selected from In and Ga. The element from group VIb can be at least one element selected from Se and S. More specifically, semiconductors such as CuInSe₂, Cu(In, Ga)Se₂ or a semiconductor including sulfurs (S) substituting for a part of the Se can be used. Generally, these semiconductors are p-type semiconductors. Among them, Cu(In, Ga)Se₂ (CIGS) can be controlled with its band gap from 1.0 eV to 1.6 eV by adjusting a solid solution ratio of In to Ga. Therefore, by using CIGS, a semiconductor layer having a desirable band gap for obtaining a high converting efficiency can be provided easily. As these chalcopyrite structured semiconductors have a high optical-absorption coefficient, they can absorb sunlight sufficiently even if they are thin. Thus, by using a flexible substrate and a chalcopyrite structured semiconductor, a flexible solar cell can be obtained. In a solar cell of Embodiment 1, a semiconductor layer that functions as an optical absorption layer generally is a thin film having a thickness of 3 μm or less.

The window layer 15 is made of a semiconductor or an insulator. For example, CdS, ZnO, ZnMgO, Zn(O,S), ZnInₓSe_{y}, InₓSe_{y} or In₂O₃ can be used as the window layer 15. Here, the materials such as ZnO, ZnMgO, ZnInₓSe_{y}, InₓSe_{y} and In₂O₃ are semiconductors but show relatively high electric insulation, and thus can be treated both as semiconductors and insulators.

Furthermore, the second window layer can be formed between the window layer 15 and the transparent conductive film 16. If the second window layer is formed, it can be formed of a semiconductor or an insulator. If a Zn(O,S) layer is used for the first window layer 15, the second window layer preferably is made of a material such as ZnO and ZnMgO. The second window layer has an effect to prevent the occurrence of a short circuit between the semiconductor layer 14 and the transparent conductive film 16, in the case where the first window layer 15 is not thick enough to cover the semiconductor layer 14 sufficiently.

The transparent conductive film 16 can be formed of, for example, ITO (In₂O₃:Sn), ZnO doped with boron (B) (ZnO:B), ZnO doped with aluminum (Al) (ZnO:Al), or ZnO doped with gallium (Ga) (ZnO:Ga). For the transparent conductive film 16, a laminate film, in which two or more layers of the above-mentioned materials are laminated, can be used.

For the extraction electrode 17, a laminate film, in which a NiCr film (or a Cr film) and an Al film (or an Ag film), for example, are laminated, can be used.

An example of a method for manufacturing the solar cell 10 will be described below. Firstly, the insulating layer 12 and the conducting layer 13 are laminated on the conductive substrate 11 in this order (Process (i)). The insulating layer 12 can be formed by, for example, a sputter method, an evaporation method, or chemical vapor deposition (CVD). The conducting layer 13 can be formed by, for example, an evaporation method or a sputter method.

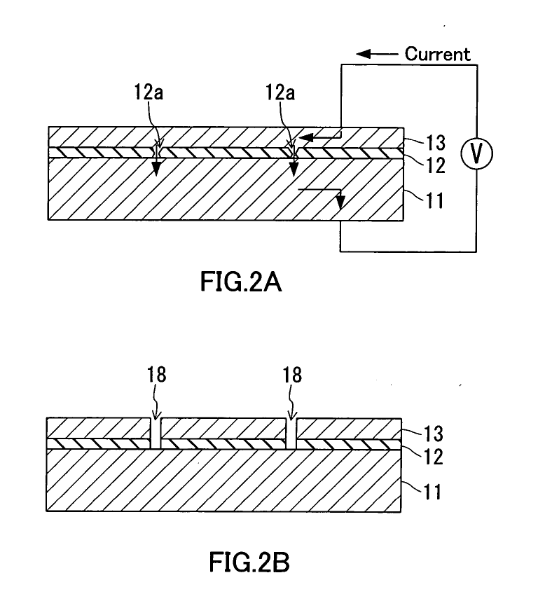

Next, the through hole 18 is formed so as to penetrate the insulating layer 12 and the conducting layer 13 (Process (iii)). An example of a method for forming the through hole 18 will be described, with reference to FIG. 2A. As shown in FIG. 2A, for example, electric voltage is applied between the conductive substrate 11 and the conducting layer 13, so that current flows between the conductive substrate 11 and the conducting layer 13. Then the current converges into the part where the resistance between the conductive substrate 11 and the conducting layer 13 is low, that is, into a low-resistance portion 12a where covering with the insulating layer 12 is not sufficient, so that the temperature is increased at that portion. As a result, the insulating layer 12 and the conducting layer 13 at the low-resistance portion 12a are burned out and removed, thereby the through hole 18 is formed in a part of the insulating layer 12 and the conducting layer 13 so as to penetrate them. The electric voltage applied between the conductive substrate 11 and the conducting layer 13 is not particularly limited, as long as the voltage allows the removal of the part where the covering with the insulating layer 12 is not sufficient, to form the through hole 18.

Thereafter, the semiconductor layer 14 which functions as an optical absorption layer is formed on the conducting layer 13 (Process (iii)). The semiconductor layer 14 can be formed by, for example, an evaporation method or a selenidation method. If adopting the selenidation method, after manufacturing a metal film composed of, for example, an element from group Ib and an element from group IIIb by a sputter method, the metal film is subjected to a heat treatment in a gaseous atmosphere that contains an element from VIb group (H₂Se) or the like. In Process (iii), the semiconductor layer 14 is formed also in the through hole 18.

Thereafter, the window layer 15 is formed by, for example, chemical bath deposition (CBD), an evaporation method, or a sputter method. Then the transparent conductive film 16 is formed on the window layer 15 by a sputter method, for example. Subsequently, the extraction electrode 17 is formed by, for example, an evaporation method or a printing method. If the above-mentioned second window layer is formed between the window layer 15 and the transparent conductive film 16, for example, a sputter method can be applied. In this manner, the solar cell 10 can be manufactured.

According to Embodiment 1, in the process of forming the semiconductor layer 14, at least one element that composes the conductive substrate 11 diffuses into the semiconductor layer 14 formed in the through hole 18. The element composing the conductive substrate 11 develops an impurity level in the semiconductor layer 14, and changes a carrier density or a conductivity type of the semiconductor layer 14. For example, although the above-mentioned CIS and CIGS, which are materials of the semiconductor layer 14, are p-type semiconductors having an adequate carrier density for solar cells, these semiconductors are changed into p-type or n-type semiconductors having high resistance when the element composing the conductive substrate 11 (such as Fe, Cr or Ni) diffuses into them. Accordingly, as shown in FIG. 3A, the semiconductor 14 formed in the through hole 18 and the semiconductor 14 located over the through hole 18 become a semiconductor layer 14a which is a p-type or n-type semiconductor having high resistance. Such a semiconductor layer 14a does not form a p-n junction with the window layer 15 of n-type (or an n-type layer configured by combining a high-resistance n-type window layer and a low-resistance n-type transparent conductive film), a junction between the semiconductor layer 14a and the window layer 15, and a junction between the window layer 15 and the transparent conductive film 16 show a substantially rectification property.

Whereas, in contrast to the junction between the conducting layer 13 and the general semiconductor 14 that is a rectification contact, a Schottky junction is formed between the semiconductor layer 14a and the conducting layer 13. As a result, as shown in FIG. 3B, a bypass diode 19b is formed in the semiconductor layer 14a, which shows a rectification property in a reverse direction to that of a p-n junction diode 19a formed in the part other than the semiconductor layer 14a. Note here that at the operating point of the solar cell, a reverse direction voltage is applied across the bypass diode 19b, and a reverse direction current in that case is so low that the bypass diode 19b does not have a large influence on the property of the solar cell in a general state.

As described above, the solar cell of Embodiment 1 is provided with a bypass diode. In a solar cell array, in which plural solar cells of Embodiment 1 are serially connected, if only a part of the solar cells does not produce electric power, a photoelectric current generated from the other solar cells flows to the next cell via the bypass diode, and thus a deterioration of the converting efficiency can be suppressed. Consequently, Embodiment 1 can provide a solar cell with a high converting efficiency and an excellent stability.

### Embodiment 2

In Embodiment 2, an example of a thin-film solar cell of the present invention will be described. More specifically, one example of an integrated solar cell module, in which plural solar cells (unit cells) are serially connected on a substrate, will be described.

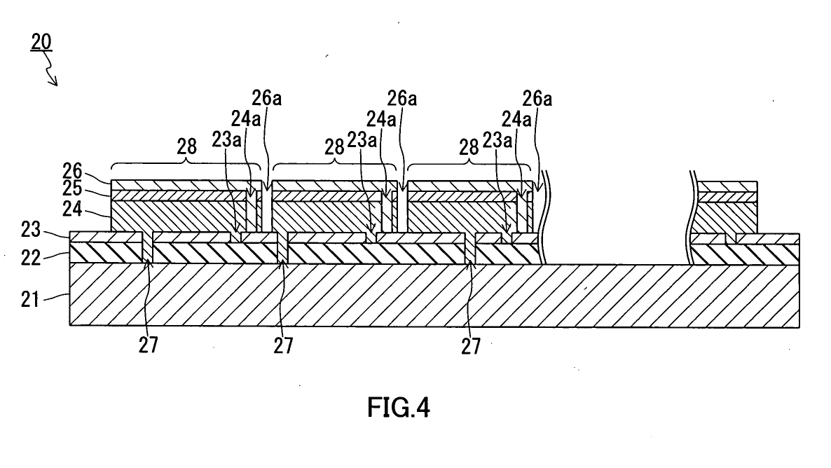

The cross-sectional view of a solar cell module of Embodiment 2 is shown in FIG. 4. As illustrated in FIG. 4, a solar cell module 20 of Embodiment 2 includes a conductive substrate 21, an insulating layer 22 formed on the conductive substrate 21, a conducting layer 23 that functions as a backside electrode and is formed on the insulating layer 22, a semiconductor layer 24 that functions an optical absorption layer and is formed on the conducting layer 23, a window layer 25 made of a semiconductor or an insulator formed on the semiconductor layer 24, and a transparent conductive film 26 formed on the window layer 25. Moreover, a second window layer made of a semiconductor or an insulator further can be provided between the window layer 25 and the transparent conductive film 26.

In a part of the insulating layer 22 and the conducting layer 23, a through hole 27 is formed so as to penetrate them. The through hole 27 is filled with a semiconductor that composes the semiconductor layer 24. Here, the semiconductor in the through hole 27 and the semiconductor over the through hole 27 include at least one element selected from the elements that compose the conductive substrate 21 that diffuses in a similar manner as in the semiconductor layer 14a in FIG. 3A, thus having characteristics different from the remaining semiconductor layer 24.

The conducting layer 23, the semiconductor layer 24 and the window layer 25 (including the second window layer, if provided between the window layer 25 and the transparent conductive film 26), and the transparent conductive film 26 are split in strips by stripe-formed grooves 23a, 24a and 26a, respectively. Each layer split in a strip shape forms plural unit cells 28. That is, each of the unit cells 28 is provided with the conducting layer 23, the semiconductor layer 24, the window layer 25 and the transparent conductive film 26 that are formed in a strip shape. The transparent conductive film 26 in the each unit cell 28 is connected to the conducting layer 23 in the adjacent unit cell 28 via the groove 24a. In this manner, all the unit cells 28 are connected serially.

For the conductive substrate 21, for example, the above-described materials for the conductive substrate 11 of Embodiment 1 can be used. Similarly, the above-described materials and configurations for the insulating layer 12, the conducting layer 13, the semiconductor layer 14, the window layer 15 and the transparent conductive film 16 of Embodiment 1 are also applicable to the insulating layer 22, the conducting layer 23, the semiconductor layer 24, the window layer 25, and the transparent conductive film 26, respectively.

An example of a method for manufacturing the solar cell 20 will be described below. The method for manufacturing the insulating layer 22, the conducting layer 23, the semiconductor layer 24, the window layer 25, the second window layer and the transparent conductive film 26 that are the same as those in Embodiment 1, is omitted.

Firstly, the insulating layer 22 and the conducting layer 23 are laminated on the conductive substrate 21 in this order (Process (i)). Then a part of the conducting layer 23 is removed to be in a stripe form, so that the conducting layer 23 is split into plural strip-shaped conducting layers. An example of a method for splitting the conducting layer is described as follows. Firstly, the insulating layer 22 is formed on the conductive substrate 21. Then a stripe-formed resist pattern is formed partially on the insulating layer 22. Thereafter, the conducting layer 23 is formed so as to cover the resist pattern, followed by peeling off the resist pattern using a solvent so as to form the stripe-formed grooves 23a. Another example of a method for splitting the conducting layer is forming the insulating layer 22 and the conducting layer 23 in this order, and then removing a part of the conducting layer 23 in a stripe form by irradiation with a laser beam or a linear plasma, so as to form the grooves 23a. The conducting layer 23 is split in a strip shape by the stripe-form grooves 23a.

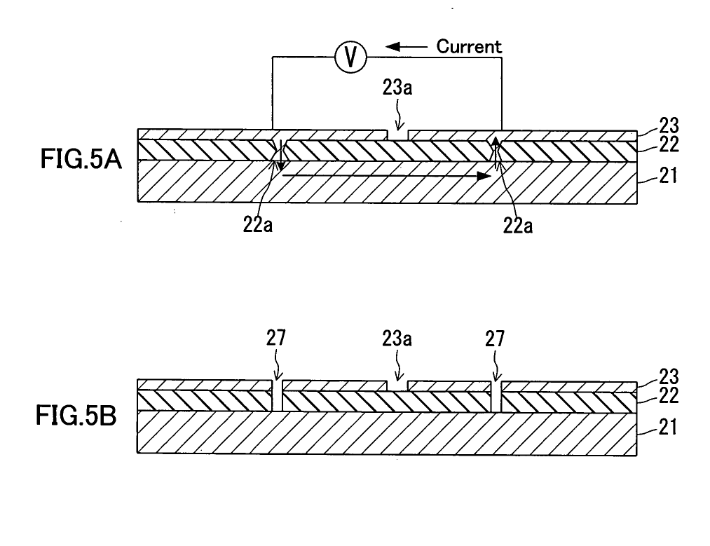

Next, a through hole 27 is formed so as to penetrate the insulating layer 22 and the conducting layer 23 (Process (ii)). An example of a method for manufacturing the through hole 27 will be described, with reference to FIG. 5A. The through hole 27 can be formed by letting an electric current flow between at least two conducting layers selected from the plural strip-shaped conducting layers 23. For example, as shown in FIG. 5A, an electric voltage is applied between the two adjacent conducting layers 23 with the groove 23a interposed therebetween. During this process, a current converges into a low-resistance portion 22a, where covering of the insulating layer 22 is not sufficient, so that heat is generated at that portion. The thus generated heat makes the insulating layer 22 and the conducting layer 23 partly burned out and removed, thereby the through hole 27 is formed as shown in FIG. 5B at a part of the insulating layer 22 and the conducting layer 23. It is also possible to form the through hole 27 by applying a voltage between the conductive substrate 21 and the conducting layer 23 so as to allow a current to flow therethrough in the same manner as that in Embodiment 1.

Thereafter, the semiconductor layer 24 is formed in the through hole 27 and on the conducting layer 23 (Process (iii)). Thereafter, the window layer 25 is formed on the semiconductor layer 24. The above-described second window layer may be formed on the window layer 25.

Thereafter, the grooves 24a are formed by removing a part of the semiconductor layer 24 and the window layer 25 to be in a stripe form by, for example, a mechanical scribe method, in which a thin film is peeled off mechanically using a metal or diamond needle. The semiconductor layer 24 and the window layer 25 (including the second window layer) are split in a strip shape by the grooves 24a.

Thereafter, the transparent conductive film 26 is formed on the window layer 25 and on the exposed part of the conducting layer 23 where the window layer 25 and the semiconductor layer 24 have been removed.

Thereafter, the grooves 26a are formed by removing a part of the semiconductor layer 24, the window layer 25 and the transparent conductive film 26 in a stripe form by, for example, a mechanical scribe method. The semiconductor layer 24, the window layer 25 (including the second window layer) and the transparent conductive film 26 are split in a strip shape by the grooves 26a. In the manner described above, an integrated solar cell module, in which plural unit cells are connected in series, can be manufactured.

According to Embodiment 2, similarly to Embodiment 1, during the process of forming the semiconductor layer 24, the element composing the conductive substrate 21 diffuses into the semiconductor layer formed in the through hole 27 and the semiconductor layer over the through hole 27. As a result, the semiconductor 24 in and around the through hole 27 is converted from a p-type semiconductor having an adequate carrier density for solar cells into a p-type or n-type high-resistance semiconductor. Accordingly, the bypass diode by Schottky junction is formed near the through hole 27, in a similar manner to Embodiment 1.

Moreover, in the present embodiment, a short circuit between the conductive substrate 21 and the conducting layer 23, which occurs by the insufficient formation of the insulating layer 22, is solved by the formation of the through hole 27. Accordingly, the value of the resistance between the adjacent strips of the conducting layers 23, which have been conductive due to the short circuit, increases. As a result, a solar cell having an excellent property can be obtained.

As described in Embodiment 1, the semiconductor layer 24 in and over the through hole 27 increases in resistance due to the impurity diffusion from the conductive substrate 21. At this part, a Schottky junction further is formed between the semiconductor layer 24 and the conductive substrate 21, in a similar manner to the interface between the semiconductor layer 24 and the conducting layer 23 near the through hole 27. Due to these two effects, electric current flowing from the semiconductor layer 24 to the conductive substrate 21 and the voltage drop resulting from it are minute, thus the property of the solar cell in a normal state is hardly affected. Therefore, a solar cell module having a serially connected structure and showing a high converting efficiency can be manufactured.

According to Embodiment 2, the converting efficiency of the solar cell can be not only prevented from deterioration by forming a bypass diode, but also improved by removing a short circuit between unit cells. Therefore, according to Embodiment 2, a solar cell module with a high converting efficiency and an excellent stability can be provided.

The following is a more specific description of the present invention by way of examples.

### EXAMPLE 1

Example 1 is directed to a solar cell of Embodiment 1 and an example of a method for manufacturing the same.

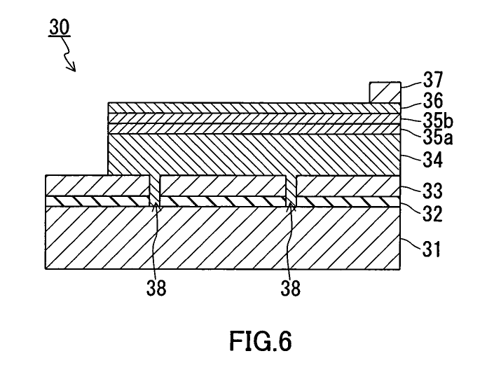

A configuration of a solar cell 30 will be described, with reference to FIG. 6. In Example 1, a stainless substrate 31 (thickness: 50 μm) for the conductive substrate 11, a SiO₂ layer 32 (thickness: 0.5 μm) for the insulating layer 12, a Mo layer 33 (thickness: 0.8 μm) for the conducting layer 13, a CIGS layer 34 (thickness: 2 μm) for the semiconductor layer 14 that functions as an optical absorption layer, a CdS layer 35a (thickness: 0.1 μm) for the first window layer of the window layer 15, a ZnO layer 35b (thickness: 0.1 μm) for the second window layer of the window layer 15, an ITO film 36 (thickness: 0.1 μm) for the transparent conductive film 16, and a laminating film 37 of NiCr/Al (overall thickness: 1.5 μm) for the extraction electrode 17 were used.

Next, a method for manufacturing a solar cell is described as follows. Firstly, a SiO₂ layer 32 was formed on a stainless substrate 31 by a sputter method. Thereafter, a Mo layer 33 was formed further on the SiO₂ layer 32 by a sputter method.

Next, a through hole 38 was formed by the method described referring to FIG. 2A. Electric voltage was firstly applied between the stainless substrate 31 and the Mo layer 33. Here, the voltage was applied like a pulse, being gradually increased as 5 V, 10 V, 15 V and 20 V. The length of time to apply one pulse was 5 seconds or shorter, and the pulse voltage applied per each voltage ranged from 1 to 5 pulses.

Thereafter, a CIGS layer 34 was formed by an evaporation method on the Mo layer 33 and a part of the stainless substrate 31 exposed by the through hole 38. Next, the substrate was dipped into a solution that contains Cd and S (sulfur) to form a CdS layer 35a (the first window layer) on the CIGS layer 34 by a chemical deposition method. Thereafter, a ZnO layer 35b (the second window layer) was formed by a sputter method, on which an ITO film 36 further was formed by a sputter method. Subsequently, a laminating film 37 of NiCr and Al are formed by an electron beam evaporation method using a shadow musk. Thereby, a solar cell was manufactured.

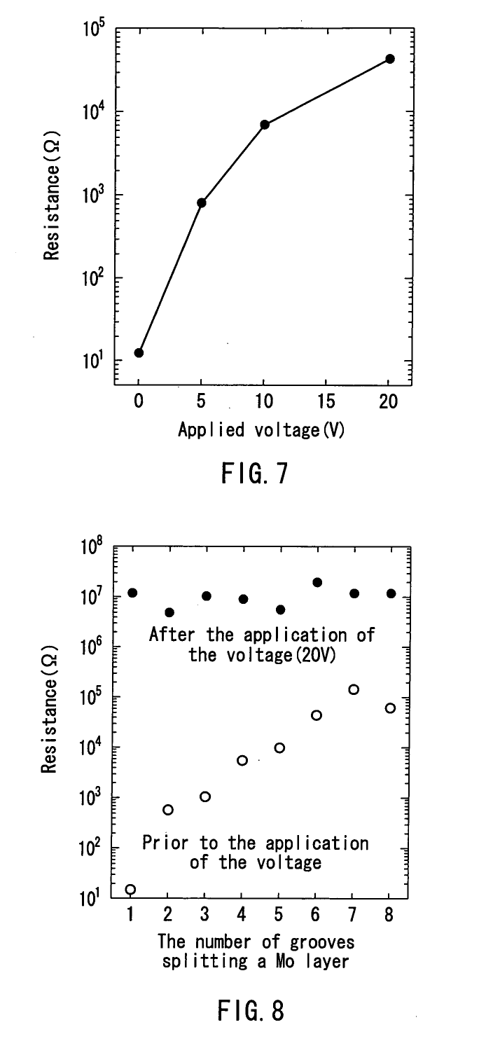

FIG. 7 shows the change of the resistance between the stainless substrate 31 and the Mo layer 33 in accordance with the applied pulse voltage. Since the resistance just after the formation of the Mo layer was as low as 12 Ω, it can be confirmed that the stainless substrate was in contact with the Mo layer at many points. The value of the resistance increased as the pulse voltage became larger. This is because each of the points where the stainless substrate was in contact with the Mo layer had a different area, and thus the resistance value thereof was different as well. When applying low voltage, current converges into the contact point of low resistance, and Mo at the point was sublimated, thereby the contact point with a large area became insulated. Subsequently, when the applied voltage was raised, current converges into the contact points with small areas, where Mo was accordingly sublimated. That is to say, in accordance with an increase in voltage, the Mo layer at the contact points is sublimated one after another from a contact point with a large area to a point with a small area, thereby increasing the resistance between the stainless substrate and the Mo layer. At the points where the Mo layer was sublimated, the through holes 38 were formed.

As a result of a measurement of a current-voltage property of the manufactured CIGS solar cell in the darkness, the current was observed to be increased when applying a reverse bias to a p-n junction diode in the solar cell. This is because a bypass diode was formed at the through hole 38. From the result of the measurement, it was ascertained that according to the solar cell and the method for manufacturing the same of the present invention, a bypass diode was formed in a solar cell. Moreover, the property of the CIGS solar cell was measured by irradiation with dummy sunlight having an air mass of 1.5 and a light intensity of 100 mW/cm². As a result of the measurement, a converting efficiency of 12.3% (voltage of open circuit: Voc=0.544 V, short circuit current density: Jsc=31.7 mA/cm², a field factor: FF=0.712) was given. Considering that the converting efficiency of the solar cell which includes no SiO₂ layer, that is, the efficiency with no bypass diode was 12.4%, it was ascertained that the converting efficiency does not deteriorate due to the existence of a bypass diode in a solar cell.

A stainless steel was used for the conductive substrate 11 in Example 1, but the use of Ti, Cr, Fe, Ni, or a metal alloy that contains two or more of these elements also gives a similar result to Example 1. The SiO₂ layer 32 was used for the insulating layer 12 in Example 1, but the use of TiO₂, Al₂O₃, Si₃N₄, TiN, a glass film, or a laminate film of these materials gives a similar result. The Mo layer 33 was used for the conducting layer 13, however, the use of a conducting layer having a two-layer structure of Mo/MoSe₂ obviously gives a similar result, because a MoSe₂ layer may be formed on a surface of the Mo layer during the formation of a CIGS layer.

### EXAMPLE 2

Example 2 is directed to a solar cell module of Embodiment 2 and another example of a method for manufacturing the same.

A specific configuration of a solar cell module of Example 2 will be described, with reference to FIG. 4. For the conductive substrate 21, the insulating layer 22, the conducting layer 23, the semiconductor layer 24 functioning as an optical absorption layer, the window layer 25 and the transparent conductive film 26, a stainless steel (thickness: 70 μm), an Al₂O₃ layer (thickness: 1 μm), a Mo layer (thickness: 0.4 μm), a CIGS layer (thickness: 1.5 μm), a Zn_{0.9}Mg_{0.1}O layer (thickness: 0.1 μm) and a ITO film (thickness: 0.6 μm) were used, respectively.

Next, a method for manufacturing the solar cell module will be described as follows. Firstly, an Al₂O₃ layer (the insulating layer 22) was formed on a stainless substrate (the conductive substrate 21) by a sputter method. Thereafter, a resist solution was arranged in a stripe form and dried, and thus a stripe-formed resist pattern was formed. Next, a Mo layer 23 further was formed by a sputter method so as to cover the Al₂O₃ layer and the resist pattern. Thereafter, the resist pattern was peeled off from the Al₂O₃ layer by being washed with pure water, and at the same time, the Mo layer piled on the resist pattern was also peeled off. Thereby, stripe-formed grooves 23a were formed in the Mo layer.

Next, through holes were formed by the method shown in FIG. 5A. More specifically, electric voltage was applied between the two adjacent Mo layers on both sides of the stripe-formed groove 23a. Here, the voltage was applied in a pattern of increasing at a certain rate until it reached a predetermined voltage, maintaining for a certain time, and decreasing at a certain rate. In this example, the rates to increase and decrease the voltage ranged from 10 V/sec. to 20 V/sec., and the time to maintain the predetermined voltage ranged from 0.1 seconds to 5 seconds. In addition, the predetermined voltage to be maintained was raised gradually as 5 V, 10 V, 15 V and 20 V, thereby the through hole 27 was formed.

Thereafter, a CIGS layer (the semiconductor layer 24) was formed by an evaporation method on the Mo layer, an exposed part of the Al₂O₃ layer where the Mo layer was peeled off in a stripe form, and a part of the stainless substrate exposed by the through hole 27. Next, a Zn_{0.9}Mg_{0.1}O layer (the window layer 25) was formed by a sputter method. Thereafter, stripe-formed grooves 24a were formed by peeling off a part of the CIGS layer and the Zn_{0.9}Mg_{0.1}O layer by a mechanical scribe method using a metal needle. Next, an ITO film (the transparent conductive film 26) was formed on the Zn_{0.9}Mg_{0.1}O layer and on a part of the Mo layer exposed by the grooves 24a. Thereafter, the ITO film, the Zn_{0.9}Mg_{0.1}O layer and the CIGS layer were partly removed by the same method as the above mechanical scribe method, so as to make grooves 26a in a stripe form. In the manner described above, the integrated solar cell module was manufactured to be provided with plural unit cells 28 which are split into strips and connected in series.

In Example 2, the Mo layer was split by the eight stripe-formed grooves 23a, and subsequently resistance between each two adjacent Mo layers on both sides of the groove was measured. Moreover, the resistance was measured again, after applying voltage up to 20 V to each two Mo layers by the above-mentioned method. The result of the measurement is shown in FIG. 8. The value of the resistance between these two Mo layers just after forming the stripe-formed grooves was distributed in the range from 10 Ω to 200 kΩ. By applying voltage up to 20 V in the above-mentioned pattern, the values of the resistance between the Mo layers on both sides of all of the grooves were raised beyond 1 M Q. This is because, by applying voltage, current flowed into the contact points, where the Mo layers on both sides of the groove were in contact with the stainless substrate via the stainless substrate of a metal, accordingly, the contact points generated heat, and thus the Mo layers at the contact points were sublimated. At the points where the Mo layer was sublimated, the through holes 27 were formed.

When the covering with Al₂O₃ as the insulation layer is not sufficient in a large area, the points where the Mo layer and the stainless substrate have short-circuit contacts are not uniform in area, and a density distribution of the contact points occurs. However, even in such a condition, the short circuit portions can be processed by applying voltage to let current flow, thus the present invention can realize the dramatic improvement in yield and repeatability.

In order to measure characteristics of one of the unit cells of the manufactured CIGS solar cell, a current-voltage property between the split Mo layers was measured in the darkness. The current was observed to be increased when applying a reverse bias to the p-n junction diode in the solar cell, thus it was confirmed a bypass diode formed at a portion of the through hole 27. Moreover, when characteristics of the CIGS solar cell were measured by irradiation with dummy sunlight with an air mass of 1.5 and a light intensity of 100 mW/cm², a converting efficiency of 10.6% was obtained. This value was approximately equal to 11.0% that is the converting efficiency of the CIGS solar cell manufactured by the same process except the point of using a glass substrate that has no bypass diode formed. Thus it was ascertained that a converting efficiency does not deteriorate by the existence of the bypass diode.

As described above, a solar cell of the present embodiment is provided with a bypass diode therein. In a general solar cell module, when a part of the solar cell does not produce electric power for any reason (such as being damaged, stained on its surface or shaded), operation of the whole module is hindered, and thus its efficiency deteriorates. On the other hand, as a solar cell of the present embodiment is provided with a bypass diode, even when a part of the solar cell does not produce electric power, the electric current produced by the other parts of cell can flow through the bypass diode. Thus the deterioration of the efficiency can be suppressed, and the damage of solar cells producing electric power can be prevented. Thereby, according to the present embodiment, a thin-film solar cell having a high converting efficiency and an excellent stability can be provided.

According to a manufacturing method of the present embodiment, since a short circuit between a conductive substrate and a conducting layer on an insulating layer can be removed during the formation of a through hole, a parallel resistance component (shunt resistance) between unit cells in an integrated solar cell module increases, and thus the efficiency of the solar cell module can be improved. Therefore, according to the manufacturing method of the present embodiment, an integrated solar cell module that has a high converting efficiency can be obtained using a conductive substrate.

Although the embodiments of the present invention have been described above with reference to the examples, it should be noted that the present invention is not limited to the embodiments described above, and can be applied to other embodiments according to the technical idea of the present invention.

### INDUSTRIAL APPLICABILITY

A solar cell of the present invention provides a high converting efficiency and an excellent stability. In addition, according to a manufacturing method of the present invention, an integrated solar cell module that has a high converting efficiency can be manufactured using a conductive substrate.

1-12. (canceled)

13. A solar cell, comprising:
a conductive substrate; and
an insulating layer, a conducting layer and a semiconductor layer that are disposed on the substrate in this order,
wherein a through hole is formed so as to penetrate the insulating layer and the conducting layer, and
the through hole is filled with a semiconductor that composes the semiconductor layer.

14. The solar cell according to claim 13, wherein at least one element selected from the elements composing the substrate diffuses into the semiconductor with which the through hole is filled.

15. The solar cell according to claim 13, wherein the substrate is made of a metal alloy comprising at least two elements selected from Ti, Cr, Fe and Ni, or stainless steel.

16. The solar cell according to claim 13, wherein the insulating layer is made of at least one selected from the group consisting of SiO₂, TiO₂, Al₂O₃, Si₃N₄, TiN and glass.

17. The solar cell according to claim 13, wherein the conducting layer comprises Mo.

18. The solar cell according to claim 13, wherein the semiconductor layer is made of a compound semiconductor comprising an element from group Ib, an element from group IIIb, and an element from group VIb.

19. The solar cell according to claim 18, wherein the element from group Ib is Cu, the element from group IIIb is at least one element selected from In and Ga, and the element from group VIb is at least one element selected from Se and S.

20. The solar cell according to claim 19,
wherein the compound semiconductor is a p-type semiconductor, and
the semiconductor with which the through hole is filled is a p-type or n-type semiconductor having higher resistance than the p-type semiconductor of the compound semiconductor.

21. A solar cell, comprising:
a conductive substrate;
an insulating layer formed on the substrate; and
a plurality of unit cells that are formed on the insulating layer and are connected in series,
wherein each unit cell comprises a conducting layer and a semiconductor layer that are disposed on the insulating layer in this order,
a through hole is formed so as to penetrate the insulating layer and the conducting layer, and
the through hole is filled with a semiconductor that composes the semiconductor layer.

22. The solar cell according to claim 21, wherein at least one element selected from the elements composing the substrate diffuses into the semiconductor with which the through hole is filled.

23. The solar cell according to claim 21, wherein the substrate is made of a metal alloy comprising at least two elements selected from Ti, Cr, Fe and Ni, or stainless steel.

24. The solar cell according to claim 21, wherein the insulating layer is made of at least one selected from the group consisting of SiO₂, TiO₂, Al₂O₃, Si₃N₄, TiN and glass.

25. The solar cell according to claim 21, wherein the conducting layer comprises Mo.

26. The solar cell according to claim 21, wherein the semiconductor layer is made of a compound semiconductor comprising an element from group Ib, an element from group IIIb, and an element from group VIb.

27. The solar cell according to claim 26, wherein the element from group Ib is Cu, the element from group IIIb is at least one element selected from In and Ga, and the element from group VIb is at least one element selected from Se and S.

28. The solar cell according to claim 27,
wherein the compound semiconductor is a p-type semiconductor, and
the semiconductor with which the through hole is filled is a p-type or n-type semiconductor having higher resistance than the p-type semiconductor of the compound semiconductor.

29. A method for manufacturing a solar cell comprising a conductive substrate, and an insulating layer, a conducting layer and semiconductor layer that are disposed on the substrate in this order, comprising the steps of:
(i) laminating the insulating layer and the conducting layer on the substrate in this order;
(ii) forming a through hole so as to penetrate the insulating layer and the conducting layer; and
(iii) forming the semiconductor layer in the through hole and over the conducting layer.

30. The method for manufacturing a solar cell according to claim 29, wherein in the step (ii) the through hole is formed by letting electric current flow between the conducting layer and the substrate.

31. The method for manufacturing a solar cell according to claim 29, further comprising a step of removing a part of the conducting layer to be in a strip shape, so that the conducting layer is split off into plural strips, which is conducted after the step (i) and before the step (ii),
wherein in the step (ii) the through hole is formed by letting electric current flow between two conducting layers selected from the plural strips of the conducting layers.
